(19) United States
(12) Patent Application Publication
(10) Pub. No.: US 2009/0115027 A1
(43) Pub. Date: May 7, 2009

(54) Method of Fabricating an Integrated Circuit

(76) Inventor: Stephan Wege, Dresden (DE)

Correspondence Address: SLATER & MATSIL, L.L.P., 17950 PRESTON ROAD, SUITE 1000, DALLAS, TX, 75252, US

(21) Appl. No.: 11/935,086

(22) Filed: Nov. 5, 2007

(51) Int. Cl. H01L 29/06; H01L 21/311

(52) U.S. Cl. 257/622; 438/696; 257/E21.585

(57) ABSTRACT

A method of fabricating an integrated circuit is disclosed. An etching process is performed in order to create a structure in a substrate. A material layer is generated during the etching process. The material layer is formed from at least one of the group of a Si/C/O composition and/or a Si/metal composition.

### TECHNICAL FIELD

The present invention relates to a method of fabricating an integrated circuit.

### BACKGROUND

One driving motivator in commercial memory cells and architecture is the desire to pack more memory capability into smaller integrated circuits. This goal necessarily involves competing trade-offs in cost, circuit complexity, power dissipation, yield, performance, and the like. Trench capacitors are known in the art as an architecture whereby the overall size (in terms of surface area or chip “real estate”) of the memory cell is reduced. The size reduction is accomplished by forming the capacitor of the memory cell in a trench.

As is known in the art, a typical DRAM cell includes a capacitor upon which is stored a charge (or no charge depending upon the cell's state) and a pass transistor, which is used to charge the capacitor during writing and in the read process to pass the charge on the capacitor to a sense amplifier.

In most recent manufacturing, planar transistors are used for the pass transistors. The associated capacitor can be formed in a deep trench. Accordingly, deep trench memory cells represent one approach to meet the challenges of providing high capacitance structures in small areas.

### BRIEF DESCRIPTION OF THE DRAWINGS

In the accompanying drawings:

FIGS. 1A and 1B illustrate deep trench structures; and

FIG. 2 illustrates a cross section of a structure generated by a method according to an embodiment of the invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

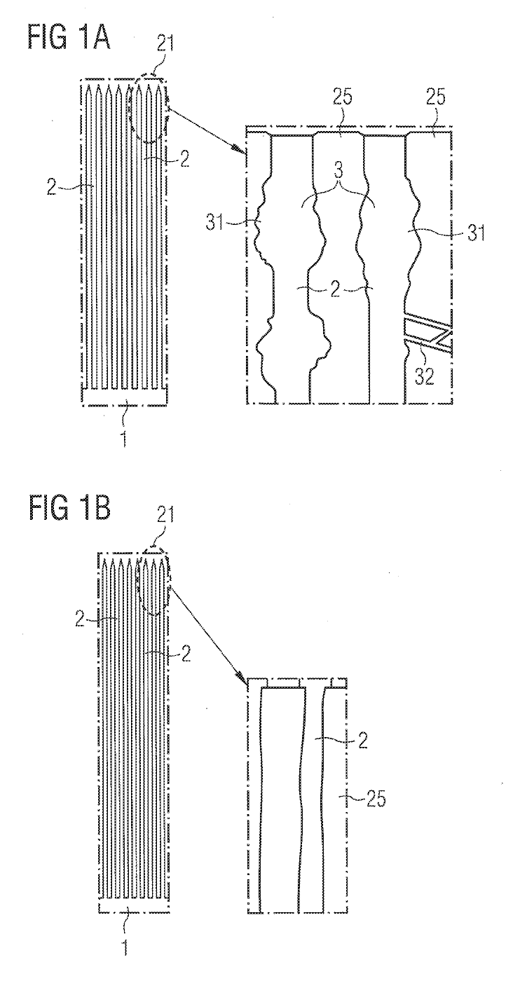

FIG. 1A illustrates a sectional view of a plurality of conventionally fabricated structures in the form of deep trench structures 2, i.e., structures having a high aspect ratio (depth to width ratio). The deep trenches 2 shown in FIG. 1A have a depth of approximately 7 μm and a width of approximately 150 nm and are created in a silicon substrate 1.

As depicted in the enlarged view of an upper section 21 of the trenches 2, they comprise a number of defects 3 which have developed during the etching of the trenches. The defects 3 are formed in a substrate portion 25 adjacent to the trenches and comprise, e.g., cavity like defects 31 having irregular contours as well as longitudinal defects 32 (worm holes).

FIG. 1B illustrates a plurality of deep trench structures 2 with dimensions similar to the dimensions of the deep trenches of FIG. 1A, the deep trenches 2 forming part of an integrated circuit. However, unlike the trenches of FIG. 1A the deep trenches 2 of FIG. 1B have been etched using a method according to one embodiment of the invention. This embodiment comprises using a conventional etching gas or a plurality of etching gases (such as HBr, NF₃ or O₂) along with a CH₄ precursor that was added to the etching gas.

Due to the CH₄ precursor a material layer in the form of a passivation layer was generated at a substrate portion (sidewall) adjacent to an etched region in the form of an opening in the substrate (upper part of the trenches 2) during the etching, the passivation layer formed from a Si/C/O (silicon/carbon/oxide; SiₓC_{y}O_{z}) composition. The Si/C/O containing passivation layer provided a protection of the trench sidewalls during the trench etching such that the number and the size of sidewall defects were reduced. This is depicted in the enlarged upper section 21 of the deep trench structures 2 showing essentially defect free trenches.

It is noted that the passivation layer can be formed as a separate layer on the sidewall of the etched part of the trenches. In another embodiment the passivation layer is formed integrally with the sidewall by modifying the substrate portion adjacent to the etched part of the trenches, e.g., by incorporating material particles into the substrate portion.

Although CH₄ has been used for generating the deep trench structures 2 of FIG. 1B, the invention includes the use of other precursors which will produce a Si/C/O passivation layer, for example tetraethyloxysilane (TEOS).

In another embodiment, a precursor is used that generates a silicon/metal composition on the sidewall of the etched portion of a structure. In this case, the precursor can comprise titanium, e.g., in the form of TiCl₄, such that a passivation layer containing a silicon/titanium composition is produced. In another example the precursor comprises tantalum such as a precursor comprising tantalum chloride.

Also, a combination of different precursors is possible such that a passivation layer comprising both a Si/C/O and a Si/metal composition is generated. For example, different precursors are used successively such that a first sidewall portion comprises Si/C/O and a second sidewall portion comprises a Si/metal composition.

If CH₄ is used as a precursor, in one embodiment of the invention, the plasma conditions are chosen such that most or essentially the entire CH₄ precursor is decomposed. In this case, the plasma conditions include, e.g., an excitation frequency in the range of approximately 40 MHz to 100 MHz, in particular 60 MHz, and an excitation power in the range of approximately 800 to 1200 Watts, in particular, 1000 Watts in particular.

In a further example, the concentration of the precursor relative to the etching gas and the plasma conditions are chosen to generate a passivation layer of the predetermined stoichiometry, i.e., the composition of the Si/C/O passivation layer can be adapted (and, e.g., adapted to the used etching gas) by the plasma conditions and the precursor concentration relative to the etching gas. The precursor can in principle be combined with all conventional etching gases.

In an embodiment of the inventive method, the precursor is added to the etching gas during the complete etching process. In another example, the precursor is added during one or more distinct periods of the etching process, only. For example, the precursor is added at the beginning and during an end phase of the etching process, while the etching process also comprises etching steps without the precursor.

It is noted that although FIG. 1B relates to etching a deep trench structure, the inventive method can of course be used for generating other structures (having other functions and/or geometries). For example, structures having a lower aspect ratio than deep trenches such as, e.g., contact structures of an integrated circuit can be formed. Also, deep trench structures with different geometries (e.g., with a circular cross section) are of course covered by the invention.

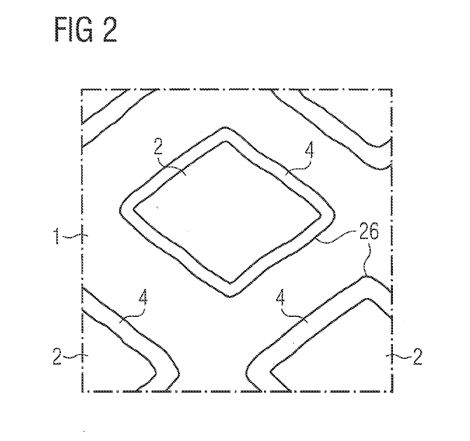

FIG. 2 depicts a top cross sectional view of a plurality of deep trenches 2 in a silicon substrate 1. The deep trenches 2 comprise side walls 26, wherein a passivation layer 4 is generated at the sidewalls 26. The passivation layer 4 comprises Si/C/O and/or a Si/metal composition.

As illustrated in FIG. 2, the passivation layer 4 essentially extends around the complete circumference of the deep trenches 2, wherein the passivation layer of this example has a thickness in the range of 6 to 12 nm. However, embodiments of the invention of course include the fabrication of passivation layers with other geometries (i.e., smaller or bigger thicknesses and/or different shapes). Also, methods according to the invention can be used to generate a passivation layer that does not cover the complete sidewall section of a structure or does not extend around the complete cross section of the structure. The passivation layer can be generated on a portion of a sidewall, only.

What is claimed is:

1. A method of fabricating an integrated circuit, the method comprising:
performing an etching process to create a structure in a substrate; and
generating a material layer during the etching process, the material layer comprising a Si/C/O composition and/or a Si/metal composition.

2. The method according to claim 1, wherein the material layer passivates a portion of the substrate adjacent an opening created by the etching process.

3. The method according to claim 2, wherein generating the material layer comprises generating a separate layer that is disposed on the portion of the substrate adjacent the opening.

4. The method according to claim 2, wherein generating the material layer comprises modifying the portion of the substrate adjacent the opening.

5. The method according to claim 1, wherein the substrate comprises silicon.

6. The method according to claim 1, wherein the etching process uses an etching gas.

7. The method according to claim 6, wherein a plasma is generated in the etching gas.

8. The method according to claim 6, wherein generating the material layer comprises adding a precursor to the etching gas.

9. The method according to claim 8, wherein the precursor comprises carbon.

10. The method according to claim 9, wherein the precursor comprises CH₄.

11. The method according to claim 10, wherein a plasma is generated in the etching gas with plasma conditions such that most of the CH₄ precursor is decomposed.

12. The method according to claim 11, wherein the plasma conditions comprise an excitation frequency in the range of approximately 40-100 MHz and an excitation power in the range of approximately 800-1200 W.

13. The method according to claim 12, wherein the plasma conditions comprise an excitation frequency of approximately 60 MHz and an excitation power of approximately 1000 W.

14. The method according to claim 8, wherein the precursor comprises tetraethyloxysilane (TEOS).

15. The method according to claim 8, wherein the precursor includes no fluorine.

16. The method according to claim 8, wherein the precursor comprises titanium or tantalum.

17. The method according to claim 16, wherein the precursor comprises TiCl₄.

18. The method according to claim 8, wherein the precursor is added to the etching gas during essentially the entire etching process.

19. The method according to claim 8, wherein the precursor is added only during one or more distinct periods of the etching process, the distinct periods being less than a complete etching period.

20. The method according to claim 6, wherein the etching gas comprises at least one material of the group consisting of HBr, NF₃ and O₂.

21. The method according to claim 1, wherein performing the etching process comprises etching a deep trench.

22. An integrated circuit formed with the method according to claim 1.

23. A semiconductor structure comprising:
a trench disposed within a semiconductor body; and
a material layer adjacent sidewalls of the trench, the material layer comprising a Si/C/O composition.

24. A semiconductor structure comprising:
a trench disposed within a semiconductor body; and
a material layer adjacent sidewalls of the trench, the material layer comprising a Si/metal composition.
